(19) United States
(12) Patent Application Publication
(10) Pub. No.: US 2025/0212620 A1
(43) Pub. Date: Jun. 26, 2025

(54) DISPLAY DEVICE

(71) Applicant: Japan Display Inc., Tokyo (JP)

(72) Inventors: Sho YANAGISAWA, Tokyo (JP); Hideyuki TAKAHASHI, Tokyo (JP)

(73) Assignee: Japan Display Inc., Tokyo (JP)

(21) Appl. No.: 18/989,345

(22) Filed: Dec. 20, 2024

(30) Foreign Application Priority Data
Dec. 21, 2023 (JP) 2023-215593

(51) Int. Cl. H10K 59/122; H10K 59/80

(52) U.S. Cl. CPC H10K 59/122; H10K 59/873

(57) ABSTRACT

According to one embodiment, a display device includes a substrate having a display area and a surrounding area, an organic insulating layer, display elements each includes a lower electrode, an upper electrode and an organic layer, a first partition between the adjacent display elements, a second partition in the surrounding area, and a dam portion which is provided in the surrounding area and surrounds the organic insulating layer and the second partition. Each of the first and second partitions includes a conductive lower portion and an upper portion. Further, an end portion of the second partition is located above the organic insulating layer and is spaced apart from the dam portion.

### CROSS-REFERENCE TO RELATED APPLICATIONS

This application is based upon and claims the benefit of priority from Japanese Patent Application No. 2023-215593, filed Dec. 21, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique which can improve the yield and reliability is required.

### SUMMARY

In general, according to at least one embodiment, a display device can comprises a substrate having a display area which displays an image and a surrounding area located around the display area, an organic insulating layer provided in the display area and the surrounding area, a plurality of display elements each of which includes a lower electrode, an upper electrode located above the lower electrode and an organic layer located between the lower electrode and the upper electrode and emitting light based on application of voltage, and is provided in the display area, a first partition provided in the display area and provided between the adjacent display elements, a second partition provided in the surrounding area and connected to the first partition, and a dam portion which is provided in the surrounding area and surrounds the organic insulating layer and the second partition. Each of the first partition and the second partition includes a conductive lower portion and an upper portion having an end portion which protrudes from a side surface of the lower portion. Further, an end portion of the second partition is located above the organic insulating layer and is spaced apart from the dam portion.

### BRIEF DESCRIPTION OF THE DRAWINGS

FIG. 1 is a diagram showing a configuration example of a display device according to an embodiment.

FIG. 2 is a schematic plan view showing an example of the layout of subpixels.

FIG. 3 is the schematic cross-sectional view of the display device along the III-III line of FIG. 2.

FIG. 4 is a schematic plan view of the display device for explaining the structure of a surrounding area.

FIG. 5 is an enlarged plan view of part of the surrounding area.

FIG. 6 is the schematic cross-sectional view of the display device along the VI-VI line of FIG. 5.

FIG. 7 is a schematic cross-sectional view in which part of FIG. 6 is enlarged.

FIG. 8A is a schematic cross-sectional view showing an example of the manufacturing process of the display device.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 8G is a schematic cross-sectional view showing a process following FIG. 8F.

FIG. 8H is a schematic cross-sectional view showing a process following FIG. 8G.

FIG. 8I is a schematic cross-sectional view showing a process following FIG. 8H.

FIG. 9 is a schematic cross-sectional view of the surrounding area according to a comparative example.

FIG. 10 is a schematic plan view of the display device according to a modified example.

### DETAILED DESCRIPTION

One or more embodiments will be described with reference to the accompanying drawings.

The present disclosure presents examples, and proper changes in keeping with the spirit of the present disclosure. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the present disclosure, including embodiments thereof. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment can be an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

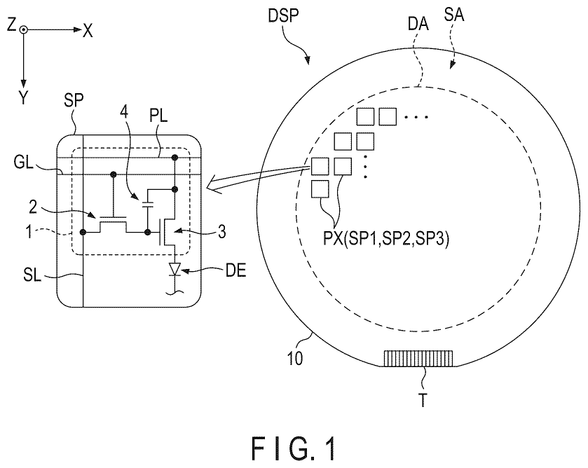

FIG. 1 is a diagram showing a configuration example of a display device DSP according to an embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 and the display area DA are circular as seen in plan view. It should be noted that the shape of each of the substrate 10 and the display area DA in plan view is not limited to a circle and may be another shape such as a rectangle, a square or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

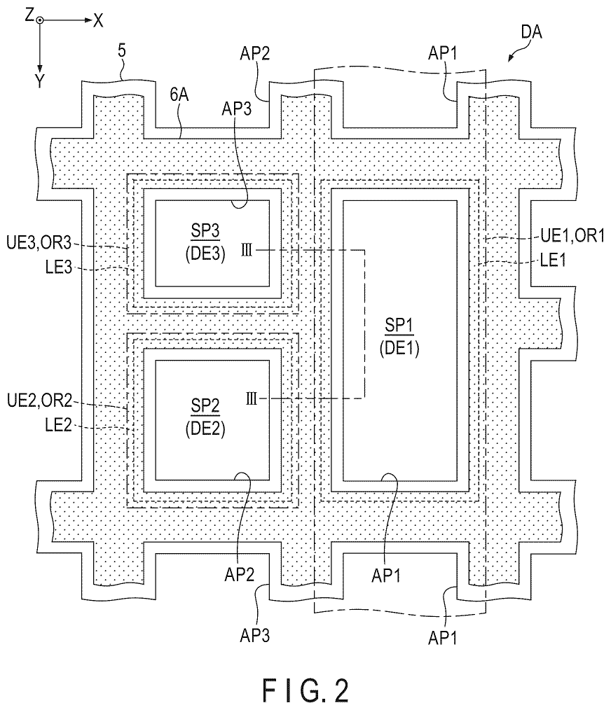

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition 6A (first partition) is provided on the rib layer 5. The partition 6A overlaps the rib layer 5 as a whole and has a planar shape similar to that of the rib layer 5. In other words, the partition 6A has an aperture in each of subpixels SP1, SP2 and SP3. From another viewpoint, each of the rib layer 5 and the partition 6A has a grating shape as seen in plan view and surrounds each of subpixels SP1, SP2 and SP3. The partition 6A functions as lines which apply common voltage to the upper electrodes UE1, UE2 and UE3.

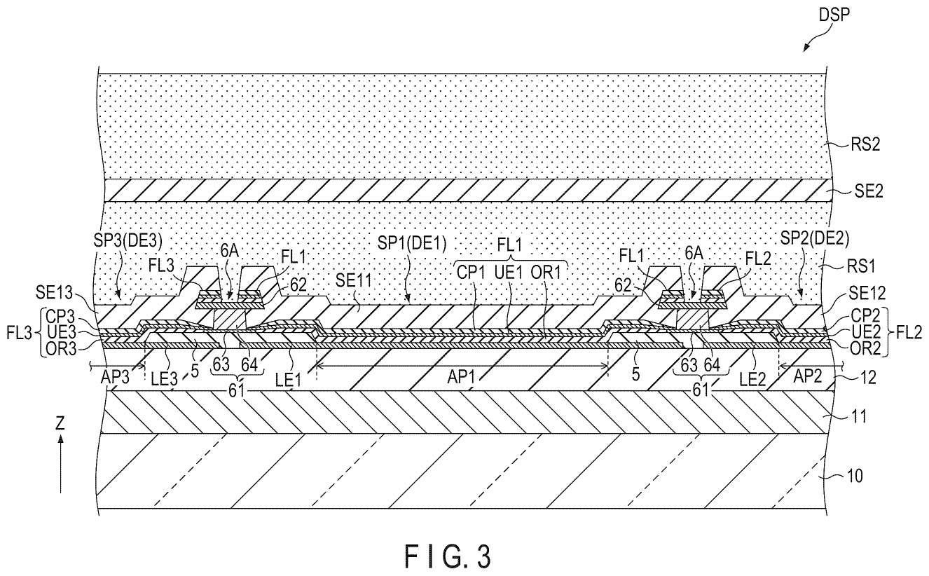

FIG. 3 is the schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6A.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6A (in other words, the portion which constitutes the display element DE1). Similarly, the stacked film FL2 is partly located on the upper portion 62. This portion is spaced apart from, of the stacked film FL2, the portion located around the partition 6A (in other words, the portion which constitutes the display element DE2). Further, the stacked film FL3 is partly located on the upper portion 62. This portion is spaced apart from, of the stacked film FL3, the portion located around the partition 6A (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6A around subpixel SP1. The sealing layer SE12 continuously covers the cap layer CP2 and the partition 6A around subpixel SP2. The sealing layer SE13 continuously covers the cap layer CP3 and the partition 6A around subpixel SP3.

In the example of FIG. 3, the stacked film FL1 and sealing layer SE11 located on the partition 6A between subpixels SP1 and SP2 are spaced apart from the stacked film FL2 and sealing layer SE12 located on this partition 6A. The stacked film FL1 and sealing layer SE11 located on the partition 6A between subpixels SP1 and SP3 are spaced apart from the stacked film FL3 and sealing layer SE13 located on this partition 6A.

The sealing layers SE11, SE12 and SE13 (first sealing layers) are covered with a resin layer RS1 (first resin layer). The resin layer RS1 is covered with a sealing layer SE2 (second sealing layer). The sealing layer SE2 is covered with a resin layer RS2 (second resin layer). The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6A comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6A. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

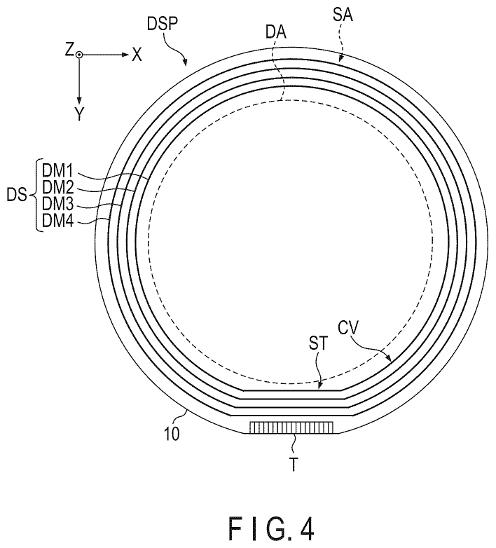

FIG. 4 is a schematic plan view of the display device DSP for explaining the structure of the surrounding area SA. The display device DSP comprises a dam structure DS provided in the surrounding area SA. In the example of FIG. 4, the dam structure DS includes annular dam portions DM1, DM2, DM3 and DM4.

The dam portion DM1 surrounds the display area DA. The dam portion DM2 surrounds the dam portion DM1. The dam portion DM3 surrounds the dam portion DM2. The dam portion DM4 surrounds the dam portion DM3.

Each of the dam portions DM1, DM2, DM3 and DM4 has an arcuate curved portion CV and a linear portion ST connected to the both end portions of the curved portion CV. The curved portions CV are concentric with, for example, the display area DA. For example, the linear portions ST are located between the display area DA and the terminal portion T and extend parallel to the X-direction.

It should be noted that the shape of the dam portion DM1, DM2, DM3 or DM4 is not limited to the example of FIG. 4. Further, the number of dam portions provided in the dam structure DS may be three or less or may be five or more.

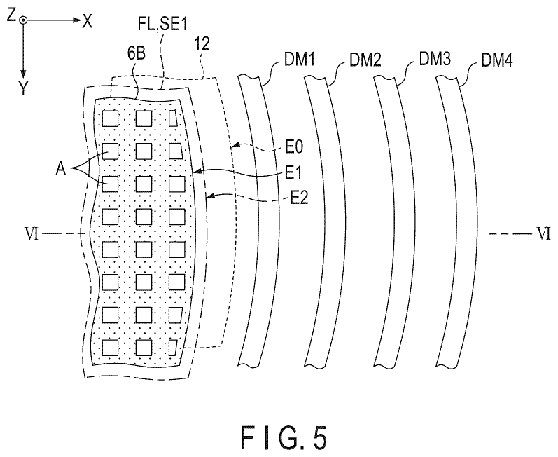

FIG. 5 is an enlarged plan view of part of the surrounding area SA. The organic insulating layer 12 described above is provided in the surrounding area SA as well. The organic insulating layer 12 is provided inside the dam portion DM1. Thus, the dam portion DM1 surrounds the organic insulating layer 12. The end portion E0 of the organic insulating layer 12 is spaced apart from the dam portion DM1.

A partition 6B is further provided in the surrounding area SA. The partition 6B is formed by the same process as the partition 6A shown in FIG. 2 and FIG. 3 and has a structure similar to that of the partition 6A.

For example, the partition 6B surrounds the display area DA together with the dam portions DM1, DM2, DM3 and DM4. The partition 6B is connected to the partition 6A described above. In other words, common voltage is applied to the partition 6B. The partition 6B may have a plurality of apertures A as shown in the figure. The apertures A are arranged at regular intervals in the X-direction and the Y-direction.

The partition 6B overlaps the organic insulating layer 12 as a whole as seen in plan view. Thus, the end portion E1 of the partition 6B is located above the organic insulating layer 12.

In the example of FIG. 5, a stacked film FL and a sealing layer SE1 are provided in the surrounding area SA. The stacked film FL is one of the stacked films FL1, FL2 and FL3 shown in FIG. 3. The sealing layer SE1 is one of the sealing layers SE11, SE12 and SE13 shown in FIG. 3. In a manner similar to that of the partition 6B, the stacked film FL and the sealing layer SE1 overlap the organic insulating layer 12 as a whole as seen in plan view.

The partition 6B, the stacked film FL and the sealing layer SE1 are provided inside the dam portion DM1. In other words, the dam portion DM1 surrounds the partition 6B, the stacked film FL and the sealing layer SE1. The end portion E1 of the partition 6B is spaced apart from the dam portion DM1. Similarly, the end portion E2 of the stacked film FL and the sealing layer SE1 is spaced apart from the dam portion DM1. The end portion E2 is located between the end portion E1 and the dam portion DM1, more specifically, between the end portion E1 and the end portion E0.

In the example of FIG. 5, the end portions E0, E1 and E2 are arcuate in a manner similar to that of the dam portion DM1. For example, each of the end portions E0, E1 and E2 may have an external shape in which the distance from the dam portion DM1 is substantially constant over the whole circumference.

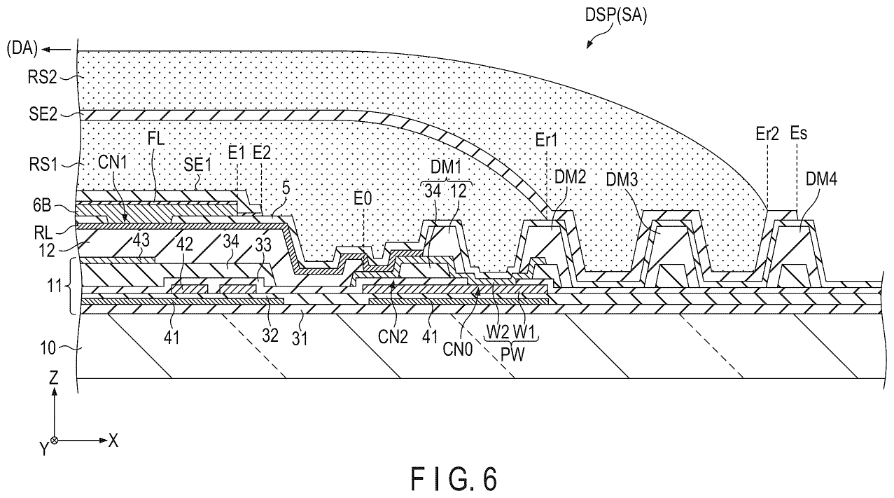

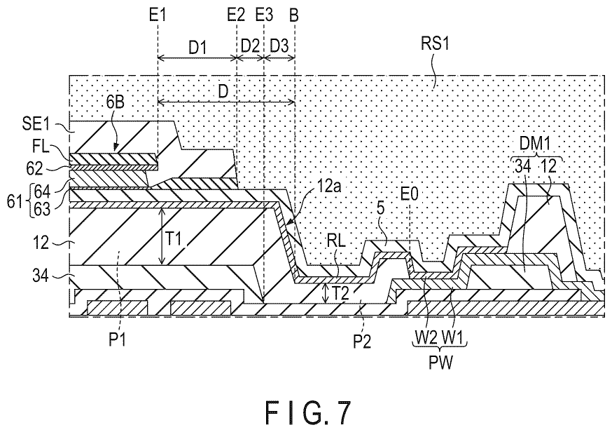

FIG. 6 is the schematic cross-sectional view of the display device DSP along the VI-VI line of FIG. 5. FIG. 7 is a schematic cross-sectional view in which part of FIG. 6 is enlarged. The circuit layer 11 shown in FIG. 3 has inorganic insulating layers 31, 32 and 33 each of which is formed of an inorganic insulating material, an organic insulating layer 34 formed of an organic insulating material, and metal layers 41, 42 and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

All of the dam portions DM1, DM2, DM3 and DM4 protrude to the upper side of the substrate 10. In the example of FIG. 6, the dam portion DM1 consists of the organic insulating layers 12 and 34. Similarly, the dam portions DM2, DM3 and DM4 consist of the organic insulating layers 12 and 34. In other words, in the embodiment, the dam portions DM1, DM2, DM3 and DM4 are formed of the same materials as the organic insulating layers 12 and 34 in the same layers as the organic insulating layers 12 and 34. It should be noted that the dam portions DM2, DM3 and DM4 may not include the organic insulating layer 34.

A power supply line PW to which common voltage is applied is provided under the dam portions DM1 and DM2. The power supply line PW has a first line W1 formed of the metal layer 42, and a second line W2 formed of the metal layer 43.

In the example of FIG. 6, the first line W1 and the second line W2 are in contact with each other in a contact portion CN0 located between the dam portions DM1 and DM2. The second line W2 is partly located between the organic insulating layers 12 and 34 in each of the dam portions DM1 and DM2.

In the surrounding area SA, a conductive relay layer RL which connects the partition 6B and the power supply line PW to each other is provided, and further, the rib layer 5 is provided. For example, the relay layer RL is formed of the same material by the same process as the lower electrodes LE1, LE2 and LE3 described above.

The relay layer RL is located on the display area DA side (the left side in the figure) relative to the dam portion DM1 and covers the organic insulating layer 12. The rib layer 5 continuously covers the relay layer RL and the dam portions DM1, DM2, DM3 and DM4. The end portion of the rib layer 5 is located on the external side relative to the dam portion DM4.

The partition 6B is provided on the rib layer 5. The partition 6B is in contact with the relay layer RL in a contact portion CN1 (first contact portion) overlapping the organic insulating layer 12 as seen in plan view. The rib layer 5 is open in the contact portion CN1.

The relay layer RL is in contact with the second line W2 of the power supply line PW in a contact portion CN2 (second contact portion). The contact portion CN2 is located between the end portion E0 of the organic insulating layer 12 and the dam portion DM1 as seen in plan view.

The partition 6B is covered with the stacked film FL. The stacked film FL is covered with the sealing layer SE1. As shown in FIG. 7, the partition 6B includes lower and upper portions 61 and 62 similar to those of the partition 6A. Further, the lower portion 61 of the partition 6B includes a bottom layer 63 and a stem layer 64. In the partition 6B, the upper portion 62 protrudes from the side surface of the stem layer 64. Thus, the end portion E1 of the partition 6B has an overhang shape in a manner similar to that of the partition 6A shown in FIG. 3.

In this manner, as shown in FIG. 6 and FIG. 7, the stacked film FL is divided near the end portion E1 of the partition 6B. The sealing layer SE1 continuously covers the portions into which the stacked film FL is divided. As the stacked film FL is divided in this manner, the path of moisture intrusion through the stacked film FL can be blocked.

The resin layer RS1, sealing layer SE2 and resin layer RS2 shown in FIG. 3 are provided above the sealing layer SE1. The resin layer RS1 covers the sealing layer SE1 and the rib layer 5. The end portion E2 of the stacked film FL and the sealing layer SE1 is covered with the resin layer RS1. When the display device DSP is manufactured, the dam portions DM1 and DM2 function to dam up the resin layer RS1 before it is cured.

In the example of FIG. 6, the end portion Er1 of the resin layer RS1 is located above the dam portion DM2. However, the position of the end portion Er1 is not limited to this example.

The sealing layer SE2 covers the end portion Er1 of the resin layer RS1. The sealing layer SE2 is in contact with the rib layer 5 in an area located on an external side (the right side in the figure) relative to the end portion Er1. In the example of FIG. 6, the end portion Es of the sealing layer SE2 is located above the dam portion DM4. The resin layer RS1 is surrounded by the sealing layer SE1, the rib layer 5 and the sealing layer SE2. By this configuration, the moisture intrusion into the resin layer RS1 is prevented.

The resin layer RS2 covers the sealing layer SE2. When the display device DSP is manufactured, the dam portions DM3 and DM4 function to dam up the resin layer RS2 before it is cured. In the embodiment, the end portion Er2 of the resin layer RS2 is located between the end portion Er1 of the resin layer RS1 and the end portion Es of the sealing layer SE2. More specifically, the end portion Er2 is located above the dam portion DM4. The resin layer RS2 covers the sealing layer SE2 above the dam portion DM3. It should be noted that the position of the end portion Er2 is not limited to the example of FIG. 6.

As shown in FIG. 7, the organic insulating layer 12 includes a first portion P1 having thickness T1 and a second portion P2 having thickness T2. Thickness T2 is less than thickness T1 (T2<T1). The second portion P2 is formed in the periphery of the first portion P1. Thus, the second portion P2 surrounds the first portion P1 as seen in plan view.

In the example of FIG. 7, the organic insulating layer 34 is provided under the first portion P1. A stepped portion 12a is generated in the organic insulating layer 12 near the end portion E3 of the organic insulating layer 34. For example, the boundary B between the first portion P1 and the second portion P2 is located at the lower end of the stepped portion 12a.

The relay layer RL covers the first portion P1, the second portion P2 and the stepped portion 12a. If the organic insulating layer 34 does not have the second portion P2, the stepped portion 12a becomes steeper. If the relay layer RL is formed so as to cover this steep stepped portion 12a, there is a possibility that the shape of the relay layer RL becomes abnormal. To the contrary, when the second portion P2 is provided, the stepped portion 12a can be eased, and the relay layer RL can be satisfactorily formed.

The end portion E1 of the partition 6B is located above the first portion P1. The end portion E2 of the stacked film FL and the sealing layer SE1 is also located above the first portion P1. The end portion E1 corresponds to the end of the upper portion 62 of the partition 6B. Both the end portion E1 and the end portion E2 are located on the display area DA side (the left side in the figure) relative to the end portion E3 of the organic insulating layer 34.

Here, the distance between the end portion E1 and the end portion E2 in plan view is defined as D1. The distance between the end portion E2 and the end portion E3 in plan view is defined as D2. The distance between the end portion E3 and the boundary B in plan view is defined as D3. In the example of FIG. 7, distance D1 is greater than distances D2 and D3 (D1>D2, D3). Distance D2 is less than distance D3 (D2<D3). For example, distance D1 is 6 μm, and distance D2 is 2 μm, and distance D3 is 4 μm.

In the embodiment, distance D (D1+D2+D3) from the boundary B to the end portion E1 in plan view is greater than or equal to thickness T1 of the first portion P1 (D≥T1). Distance D is desirably greater than or equal to 4 μm, and is more desirably 10 μm.

It should be noted that the sectional structure shown in FIG. 6 and FIG. 7 can be applied to any position of the surrounding area SA. For example, the surrounding area SA has the sectional structure shown in FIG. 6 and FIG. 7 over the whole circumference. However, for example, the sectional structure near the terminal portion T may be different from that of the other area of the surrounding area SA.

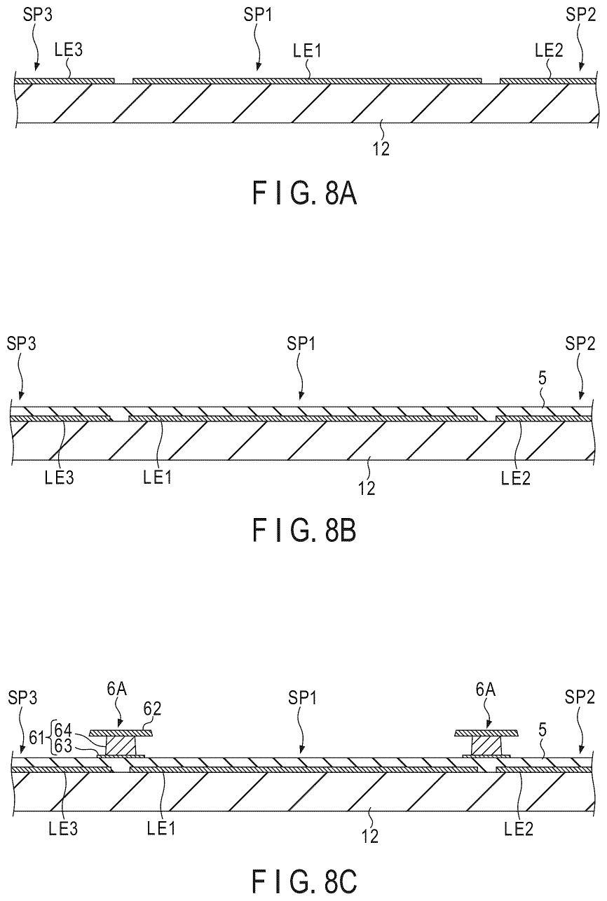

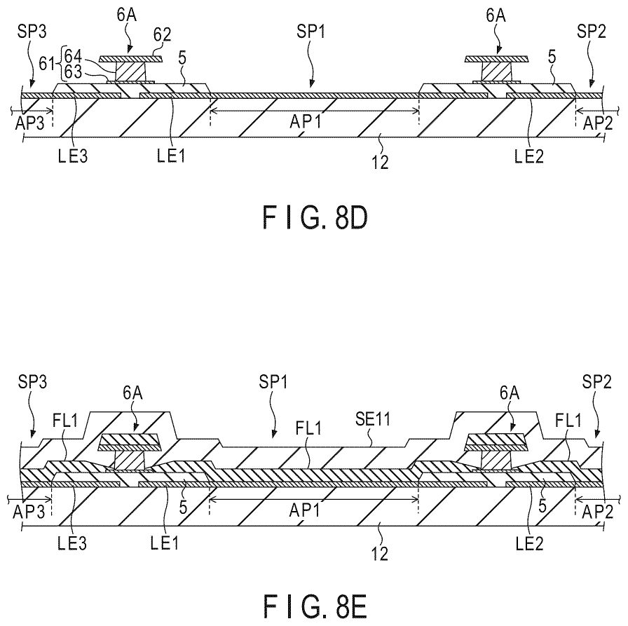

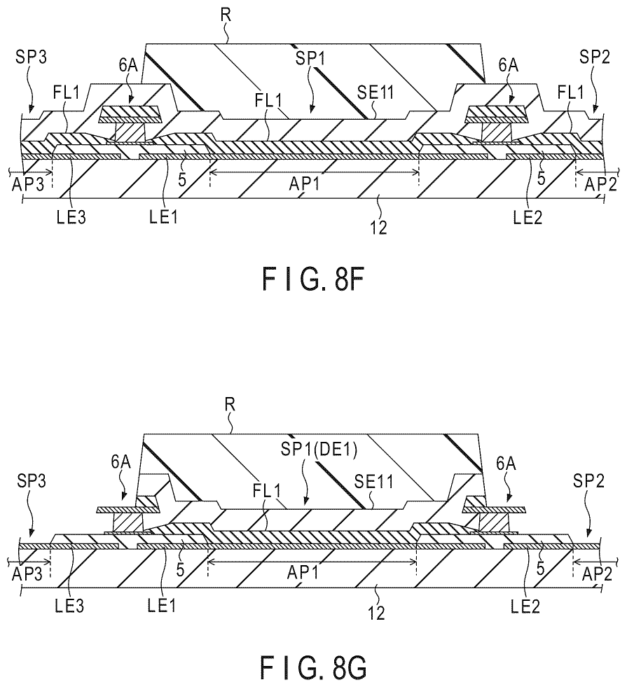

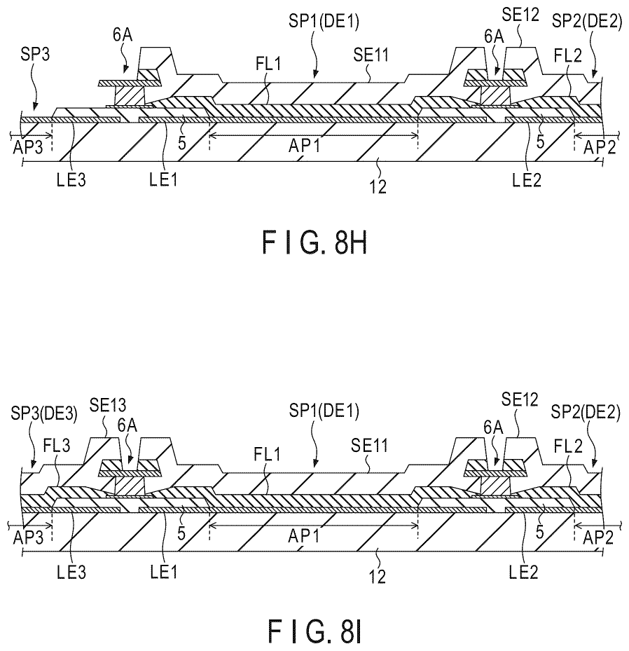

Now, this specification explains an example of the manufacturing method of the display device DSP. Each of FIG. 8A to FIG. 8I is a schematic cross-sectional view showing the manufacturing process of the display device DSP. In FIG. 8A to FIG. 8I, the display area DA is mainly looked at, and the elements located under the organic insulating layer 12 are omitted.

To form the display device DSP, first, the circuit layer 11 and the organic insulating layer 12 are formed on the substrate 10. Subsequently, as shown in FIG. 8A, the lower electrodes LE1, LE2 and LE3 are formed on the organic insulating layer 12.

Subsequently, as shown in FIG. 8B, the rib layer 5 which covers the organic insulating layer 12 and the lower electrodes LE1, LE2 and LE3 is formed. For example, chemical vapor deposition (CVD) can be used for the formation of the rib layer 5.

Further, as shown in FIG. 8C, the partition 6A is formed on the rib layer 5. Specifically, first, the base layers of the bottom layer 63, the stem layer 64 and the upper portion 62 are formed, and these layers are patterned by etching. The partition 6B shown in FIG. 5 to FIG. 7 is formed by the same process as the partition 6A.

After the formation of the partitions 6A and 6B, as shown in FIG. 8D, the pixel apertures AP1, AP2 and AP3 are formed in the rib layer 5 by dry etching. In addition to this process, a plurality of dry etching processes are performed for the rib layer 5. For example, these dry etching processes include etching for forming the aperture of the contact portion CN1 in the rib layer 5 in the surrounding area SA.

After the formation of the rib layer 5 and the partitions 6A and 6B, a process for forming the display elements DE1, DE2 and DE3 is performed. In the present embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 8E, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE11 is formed by CVD.

The stacked film FL1 and the sealing layer SE11 are formed in the surrounding area SA as well as the display area DA. The stacked film FL1 is divided into a plurality of portions by the partitions 6A and 6B having overhang shapes. The sealing layer SE11 continuously covers the portions into which the stacked film FL1 is divided, and the partitions 6A and 6B.

Subsequently, the stacked film FL1 and the sealing layer SE11 are patterned. In this patterning, as shown in FIG. 8F, a resist R is provided on the sealing layer SE11. The resist R covers subpixel SP1 and part of the partition 6A around the subpixel.

Subsequently, as shown in FIG. 8G, the portions of the stacked film FL1 and the sealing layer SE11 exposed from the resist R are removed by etching using the resist R as a mask. In other words, of the stacked film FL1 and the sealing layer SE11, the portions which overlap the lower electrode LE1 remain, and the other portions are removed. By this process, the display element DE1 is formed in subpixel SP1. This etching could include wet etching and dry etching processes which are performed in order for the sealing layer SE11, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE12 are formed in the entire display area DA and surrounding area SA. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partitions 6A and 6B having overhang shapes. The sealing layer SE12 continuously covers the portions into which the stacked film FL2 is divided, and the partitions 6A and 6B. By patterning these stacked film FL2 and sealing layer SE2, the display element DE2 is formed in subpixel SP2 as shown in FIG. 8H.

The display element DE3 is formed by a procedure similar to the procedures of the display elements DE1 and DE2. Specifically, when the display element DE3 is formed, the stacked film FL3 and the sealing layer SE13 are formed in the entire display area DA and surrounding area SA. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE13 is formed by CVD. The stacked film FL3 is divided into a plurality of portions by the partitions 6A and 6B having overhang shapes. The sealing layer SE13 continuously covers the portions into which the stacked film FL3 is divided, and the partitions 6A and 6B. By patterning these stacked film FL3 and sealing layer SE13, the display element DE3 is formed in subpixel SP3 as shown in FIG. 8I.

After the display elements DE1, DE2 and DE3 are formed, the resin layer RS1, sealing layer SE2 and resin layer RS2 shown in FIG. 3 are formed in order.

The stacked film FL shown in FIG. 5 to FIG. 7 is, for example, the stacked film FL1 which is formed firstly among the stacked films FL1, FL2 and FL3. Similarly, the sealing layer SE1 is the sealing layer SE11 which is formed firstly among the sealing layers SE11, SE12 and SE13. When the sealing layer SE11 which is formed firstly is left in the surrounding area SA in this manner, the surrounding area SA can be protected from etching which is performed at the time of forming the display elements DE2 and DE3.

As another example, the stacked film FL may be the stacked film FL3 which is formed lastly among the stacked films FL1, FL2 and FL3. Similarly, the sealing layer SE1 may be the sealing layer SE13 which is formed lastly among the sealing layers SE11, SE12 and SE13.

The stacked films FL1, FL2 and FL3 formed by vapor deposition may have poor adherence to the base. Therefore, the stacked films FL1, FL2 and FL3 and the sealing layers SE11, SE12 and SE13 which cover these stacked films may be removed from the base when the display device DSP is manufactured.

This removal easily occurs in a case where the stacked films FL1, FL2 and FL3 are continuously formed in a wide range. In the display area DA, the stacked films FL1, FL2 and FL3 are divided into pieces by the partition 6A. Thus, the removal described above is prevented.

Further, in this embodiment, the partition 6B having the apertures A is provided in the surrounding area SA. By this configuration, the stacked films FL1, FL2 and FL3 are divided into pieces in the surrounding area SA as well, and the removal described above is prevented.

Moreover, for example, the effect explained below can be obtained from the configuration shown in FIG. 7.

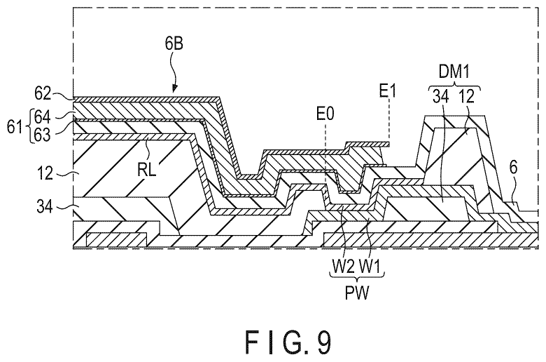

FIG. 9 is a schematic cross-sectional view of the surrounding area SA according to a comparative example of the embodiment. In the example of this figure, compared to the example of FIG. 7, the end portion E1 of the partition 6B is located near the dam portion DM1. Specifically, the end portion E1 is located between the end portion E0 of the organic insulating layer 12 and the dam portion DM1 and faces the side surface of the dam portion DM1.

In this configuration, for example, the narrow area located between the end portion E1 and the dam portion DM1 is not easily filled with the resist which is provided at the time of forming the pixel apertures AP1, AP2 and AP3 in the rib layer 5. If a cavity is generated as this area is not sufficiently filled with the resist, there is a possibility that the cavity expands and the resist bursts when the resist is dried under a reduced-pressure environment. If the shape of the resist becomes abnormal in this manner, the rib layer 5 is not normally etched.

Further, a stress is easily concentrated on the end portion E1 when a stripper for stripping the resist flows through the narrow area located between the end portion E1 and the dam portion DM1. Thus, the upper portion 62 may be pressed on the upper side in the end portion E1, and thus, the upper portion 62 may be removed from the stem layer 64. If the abnormal shape is caused in the end portion E1 of the partition 6B in this manner, the stacked film FL and sealing layer SE1 subsequently formed are easily removed.

To the contrary, in the embodiment, as shown in FIG. 7, the end portion E1 is located above the organic insulating layer 12 and is spaced apart from the dam portion DM1. In this configuration, the area located between the end portion E1 and the dam portion DM1 can be easily filled with the resist. In addition, the concentration of a stress by the stripper in the comparative example does not easily occur. Thus, the abnormal shape of the end portion E1 can be also prevented. As a result, the removal of the stacked film FL and the sealing layer SE1 can be also prevented.

To form the end portion E1 having a satisfactory shape, the upper surface of the organic insulating layer 12 as the base of the end portion E1 should be preferably flat. In this regard, when distance D is greater than or equal to thickness T1 of the first portion P1 of the organic insulating layer 12 or greater than or equal to 4 μm as explained with reference to FIG. 7, the end portion E1 can be formed on the flat upper surface which avoids the effect of the stepped portion 12a.

As described above, the embodiment can prevent the removal of the stacked film FL and the abnormal shape of the resist in the surrounding area SA and improve the yield of the display device DSP. In addition, the reliability of the display device DSP can be improved by preventing the moisture intrusion into the inside of the display device DSP.

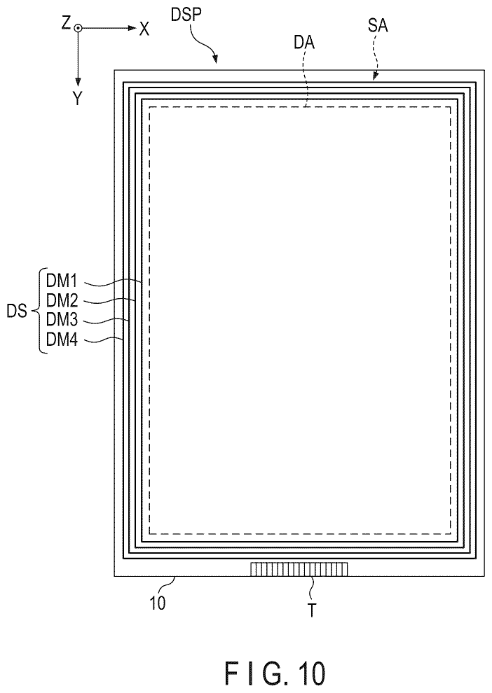

FIG. 10 is a schematic plan view of the display device DSP according to a modified example of the embodiment. In the example of this figure, the substrate 10, the display area DA and the dam portions DM1, DM2, DM3 and DM4 are rectangular. Even in a case where each of the substrate 10 and the display area DA has a shape other than a circle in this manner, the configurations shown in FIG. 5 to FIG. 7 can be applied to the surrounding area SA.

This configuration can provide a display device which can realize the improvement of the yield or reliability.

Various modification examples which may be conceived by a person of ordinary skill in the art in the scope of the idea of the present disclosure will also fall within the scope of the disclosure. For example, even if a person of ordinary skill in the art arbitrarily modifies the above embodiments by adding or deleting a structural element or changing the design of a structural element, or adding or omitting a step or changing the condition of a step, all of the modifications fall within the scope of the present disclosure.

Further, other effects which may be obtained from each embodiment and are self-explanatory from the descriptions of the specification and the corresponding drawings.

What is claimed is:

1. A display device comprising:
a substrate having a display area which displays an image and a surrounding area located around the display area;
an organic insulating layer in the display area and the surrounding area;
a plurality of display elements each of which includes a lower electrode, an upper electrode located above the lower electrode and an organic layer located between the lower electrode and the upper electrode and emitting light based on application of voltage, and is provided in the display area;
a first partition in the display area and provided between the adjacent display elements;
a second partition in the surrounding area and connected to the first partition; and
a dam portion in the surrounding area and surrounds the organic insulating layer and the second partition, wherein
each of the first partition and the second partition includes a conductive lower portion and an upper portion having an end portion which protrudes from a side surface of the lower portion, and
an end portion of the second partition is located above the organic insulating layer and is spaced apart from the dam portion.

2. The display device of claim 1, wherein
the second partition surrounds the display area together with the dam portion.

3. The display device of claim 1, wherein
the dam portion is formed of a same material as the organic insulating layer.

4. The display device of claim 1, wherein
the organic insulating layer includes:
a first portion; and
a second portion in a periphery of the first portion and is thinner than the first portion.

5. The display device of claim 4, wherein
the end portion of the second partition is located above the first portion.

6. The display device of claim 5, wherein
a distance from a boundary between the first portion and the second portion to the end portion of the second partition in plan view is greater than or equal to a thickness of the first portion.

7. The display device of claim 5, wherein
a distance from a boundary between the first portion and the second portion to the end portion of the second partition in plan view is greater than or equal to 4 μm.

8. The display device of claim 1, further comprising a rib layer formed of an inorganic insulating material and located under the second partition, wherein
the rib layer covers the dam portion.

9. The display device of claim 8, further comprising a first sealing layer which covers a stacked film including the organic layer and the upper electrode, wherein
each of the stacked film and the first sealing layer is partly provided in the surrounding area.

10. The display device of claim 9, wherein
an end portion of each of the stacked film and the first sealing layer is located between the end portion of the second partition and the dam portion.

11. The display device of claim 10, wherein
the end portion of each of the stacked film and the first sealing layer is located above the organic insulating layer.

12. The display device of claim 10, wherein
the stacked film is divided by the end portion of the second partition.

13. The display device of claim 12, further comprising a first resin layer which covers the first sealing layer, wherein
the end portion of each of the stacked film and the first sealing layer is covered with the first resin layer.

14. The display device of claim 13, further comprising a second sealing layer which covers the first resin layer, wherein
the second sealing layer is in contact with the rib layer in an area located on an external side relative to an end portion of the first resin layer.

15. The display device of claim 14, further comprising a second resin layer which covers the second sealing layer.

16. The display device of claim 1, further comprising:
a power supply line provided in the surrounding area; and
a conductive relay layer which is provided in the surrounding area and connects the second partition and the power supply line to each other.

17. The display device of claim 16, wherein
the second partition is in contact with the relay layer in a first contact portion which overlaps the organic insulating layer as seen in plan view.

18. The display device of claim 17, wherein
the relay layer is in contact with the power supply line in a second contact portion located between an end portion of the organic insulating layer and the dam portion as seen in plan view.

19. The display device of claim 1, wherein
the display area is circular, and
the dam portion has a curved portion which is arcuate along the display area.

20. The display device of claim 19, further comprising a terminal portion provided in the surrounding area, wherein
the dam portion further has a linear portion which connects both end portions of the curved portion to each other, and
the linear portion is located between the display area and the terminal portion as seen in plan view.
